(19) United States
(12) Patent Application Publication
(10) Pub. No.: US 2024/0063292 A1
(43) Pub. Date: Feb. 22, 2024

(54) SEMICONDUCTOR STRUCTURES AND FABRICATION USING SUBLIMATION

(71) Applicant: MACOM Technology Solutions Holdings, Inc., Lowell, MA (US)

(72) Inventor: Gregg Jessen, Amherst, NH (US)

(21) Appl. No.: 18/449,310

(22) Filed: Aug. 14, 2023

Related U.S. Application Data
(60) Provisional application No. 63/371,572, filed on Aug. 16, 2022.

(51) Int. Cl. H01L 29/66; H01L 29/778; H01L 21/311

(52) U.S. Cl. CPC H01L 29/66462; H01L 29/7786; H01L 21/31144

(57) ABSTRACT

Semiconductor structures and methods of fabricating semiconductor structures using sublimation are described. An example method includes forming an opening through a mask layer over a wafer. The wafer includes a substrate, a channel layer over the substrate, a barrier layer over the channel layer, and a cap layer over the barrier layer. The method also includes subliming away a region of the cap layer, within the opening in the mask layer, to form an opening in the cap layer down to a top surface of the barrier layer. The material properties of the cap layer, as compared to the barrier layer, can be relied upon to form the opening in the cap layer down to the top surface of the barrier layer using sublimation, with high selectivity. Sublimation will stop with higher precision and selectivity at the interface between the cap layer and the barrier layer, as compared to etching.

### CROSS-REFERENCE TO RELATED APPLICATIONS

This application claims the benefit of and priority to U.S. Provisional Application No. 63/371,572, filed Aug. 16, 2022, titled “SEMICONDUCTOR STRUCTURE FABRICATION USING SUBLIMATION,” the entire contents of which are hereby incorporated herein by reference.

### BACKGROUND

The miniaturization of semiconductor devices is a continuing goal, among others, in semiconductor manufacturing. A number of semiconductor materials processing tools are available to form active devices, including transistors and other devices, in integrated formats using a range of semiconductor materials. Semiconductor engineers continue to seek new processes, using currently-available and emerging processing tools, to form advanced semiconductor devices using a range of semiconductor materials.

### SUMMARY

Semiconductor structures and methods of fabricating semiconductor structures using sublimation are described. An example method of fabricating a semiconductor structure includes forming an opening through a mask layer over a wafer. The wafer includes a substrate, a channel layer over the substrate, a barrier layer over the channel layer, and a cap layer over the barrier layer. The method also includes subliming away a region of the cap layer, within the opening in the mask layer, to form an opening in the cap layer down to a top surface of the barrier layer. The material properties of the cap layer, as compared to the barrier layer, can be relied upon to form the opening in the cap layer down to the top surface of the barrier layer using sublimation, with high selectivity. Sublimation will stop with higher precision and selectivity at the interface between the cap layer and the barrier layer, as compared to etching. The method also includes depositing a conductive material into the opening in the cap layer in some cases. According to aspects of the embodiments, the barrier layer includes a first material, the cap layer includes a second material, and the second material sublimes away at a lower temperature than the first material. The barrier layer includes aluminum nitride and the cap layer includes gallium nitride in one example. The barrier layer includes aluminum nitride and the cap layer includes an aluminum gallium nitride alloy in another example.

The subliming is performed in a vacuum environment inside a processing chamber within a temperature range in some cases. As one example, the subliming is performed in a vacuum environment at a pressure of greater than or equal to 10⁻⁸ Torr and a temperature of greater than or equal to 750° C. and less than or equal to 1300° C. inside the processing chamber.

In other aspects, before depositing the conductive material, the method includes forming an insulating layer over a top surface of the barrier layer within the opening in the cap layer. In other cases, before depositing the conductive material, the method includes forming a recap layer of semiconductor materials over a top surface of the barrier layer within the opening in the cap layer.

In other aspects, forming the opening can include forming at least two openings through the mask layer, and subliming away the region of the cap layer includes subliming away a respective region of the cap layer within each of the at least two openings in the mask layer, to form at least two openings in the cap layer down to a top surface of the barrier layer. In this case, depositing the conductive material includes depositing the conductive material into the at least two openings in the cap layer.

Other embodiments include semiconductor structures fabricated using sublimation. An example semiconductor structure includes a substrate, a channel layer over the substrate, a barrier layer over the channel layer, a cap layer over the channel layer, and a conductive material in the sublimed opening. The cap layer includes a sublimed opening which extends from a top surface of the channel layer to a top surface of the barrier layer.

According to aspects of the embodiments, the barrier layer includes a first material, the cap layer includes a second material, and the second material sublimes away at a lower temperature than the first material. The barrier layer includes aluminum nitride and the cap layer includes gallium nitride in one example. The barrier layer includes aluminum nitride and the cap layer includes an aluminum gallium nitride alloy in another example. The barrier layer has a thickness between 0.3-5 nm in one example, and other thicknesses can be relied upon. The cap layer also includes an etched opening and conductive material in the etched opening in some cases. The semiconductor device can also include an insulating layer between the top surface of the barrier layer and the conductive material in the sublimed opening.

The methods can be relied upon to form a range of different semiconductor devices, including diodes, transistors, and other active and passive devices. A method of fabricating a transistor, as one example, includes forming openings through a mask layer over a wafer. The wafer includes a channel layer, a barrier layer, and a cap layer over a substrate in one example, with the channel layer over the substrate, the barrier layer over the channel layer, and the cap layer over the barrier layer. The method also includes subliming away a first region of the cap layer, within a first opening in the mask layer, to form a first opening through the cap layer. The first opening is formed through the cap layer and down to the barrier layer. The method also includes etching away a second region of the cap layer, within a second opening in the mask layer, to form a second opening through the cap layer. The method also includes depositing a conductive material into the first opening for a gate of the transistor and into the second opening for a drain or a source of the transistor.

In aspects of the embodiments, the wafer includes the barrier layer over the substrate, the channel layer over the barrier layer, a stop layer over the channel layer, and the cap layer over the stop layer. The stop layer includes aluminum nitride and the cap layer comprises an aluminum gallium nitride alloy in one example, and the first opening is formed through the cap layer and down to the stop layer. In other aspects, the method also includes, before depositing the conductive material, forming an insulating layer within the first opening in the cap layer. In other aspects, the method also includes, before depositing the conductive material, depositing semiconductor materials within the first opening in the cap layer.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1A illustrates a sectional view of a semiconductor material wafer according to aspects of the embodiments.

FIG. 1B illustrates a sectional view of another semiconductor material wafer according to aspects of the embodiments.

FIG. 2 illustrates a process for the manufacture of semiconductor structures using sublimation according to aspects of the embodiments.

FIG. 3 illustrates a sectional view of the wafer shown in FIG. 1A with a mask layer and an opening formed in the mask layer according to aspects of the embodiments.

FIG. 4A illustrates a sectional view of the wafer shown in FIG. 3 with an opening formed in a cap layer of the wafer according to aspects of the embodiments.

FIG. 4B illustrates a sectional view of the wafer shown in FIG. 1B with an opening formed in a cap layer of the wafer according to aspects of the embodiments.

FIG. 5 illustrates a sectional view of the wafer shown in FIG. 4 with a deposited layer of semiconductor materials according to aspects of the embodiments.

FIG. 6 illustrates a sectional view of the wafer shown in FIG. 4 with an insulating layer according to aspects of the embodiments.

FIG. 7 illustrates a sectional view of the wafer shown in FIG. 6 with a conductive material formed in the opening in the cap layer according to aspects of the embodiments.

FIG. 8 illustrates a sectional view of the wafer shown in FIG. 7 with the mask layer removed according to aspects of the embodiments.

FIG. 9 illustrates an additional process for the manufacture of semiconductor structures according to aspects of the embodiments.

FIG. 10 illustrates a sectional view of the wafer shown in FIG. 1A with a mask layer and openings formed in the mask layer according to aspects of the embodiments.

FIG. 11A illustrates a sectional view of the wafer shown in FIG. 1A with openings formed in the wafer according to aspects of the embodiments.

FIG. 11B illustrates a sectional view of the wafer shown in FIG. 1B with openings formed in the wafer according to aspects of the embodiments.

FIG. 12A illustrates a sectional view of the wafer shown in FIG. 1A with openings formed in the wafer according to aspects of the embodiments.

FIG. 12B illustrates a sectional view of the wafer shown in FIG. 1B with openings formed in the wafer according to aspects of the embodiments.

FIG. 13 illustrates a sectional view of the wafer shown in FIG. 12A with materials in the openings according to aspects of the embodiments.

### DETAILED DESCRIPTION

A semiconductor material structure or wafer can include a number of layers of semiconductor materials. A wafer can include different types or compositions of semiconductor materials in layers formed over a substrate of silicon (Si), silicon carbide (SiC), or other substrate. The respective material compositions of the semiconductor materials in the layers, the dopants (either unintentional impurities or intentionally-added dopants) used in the layers, the arrangement of the layers, the thicknesses of the layers, and other aspects of a wafer factor into the range of techniques that can be relied upon to process the layers to form active devices, including transistors, using the wafers.

As noted above, the miniaturization of semiconductor devices is a continuing goal, among others, in semiconductor manufacturing. A range of semiconductor materials processing tools are available to form active devices, including transistors, diodes, and other devices, as well as to form passive devices including capacitors, inductors, resistors, and other devices in integrated formats. Semiconductor engineers continue to seek new processes, using currently-available and emerging processing tools, to form advanced semiconductor devices using semiconductor materials and wafers. One goal of semiconductor manufacturing is to form smaller devices, although it can be difficult to maintain the level of precision needed for desirable device characteristics as devices are miniaturized. For example, precise vertical etching techniques are needed for lateral scaling of transistors (e.g., reducing the gate length of transistors).

In the context outlined above, a number of semiconductor processing techniques are described herein to manufacture semiconductor structures and devices on wafers with higher accuracy than using other methods. The techniques can be applied to manufacture semiconductor structures and devices on wafers having relatively thin layers, but the concepts are not limited to use with wafers having layers of any particular thickness. The techniques exploit the respective phase properties of different material layers and heterostructures in semiconductor structures using differences in temperature and pressure to achieve thermal decomposition and desorption of the atomic species, which occurs during sublimation. The techniques can be relied upon to form smaller devices with higher precision by subliming away certain materials with high selectivity and precision (e.g., even down to the atomic scale).

As a type of thermal decomposition, sublimation involves the transition of matter or materials from solid to gaseous states, and evaporation and desorption are related terms directed to phase changes of materials. Decomposition and desorption of materials can occur during sublimation under certain temperature and pressure conditions for a composition of matter, including III-V and III-Nitride materials.

According to aspects of the embodiments, in a semiconductor structure including two or more layers of semiconductor materials, the materials of first and second layers in the structure can be respectively selected such that the first layer will sublime away at a lower temperature than the second layer with high selectivity at a given pressure. In some examples described herein, a first layer of gallium nitride (GaN) will sublime away at a given temperature and pressure, whereas a second layer of aluminum nitride (AlN) will not sublime away at the temperature and pressure. The sublimation of the first layer of GaN without the sublimation of the second layer of AlN can be relied upon to selectively define features in semiconductor structures according to the embodiments. The sublimation away of the material or materials of the first layer down to, but not including, the material or materials of the second layer can be relied upon to selectively define features in devices formed in III-V materials, such as III-Nitride devices, according to the embodiments.

An example method includes forming an opening through a mask layer over a wafer. The wafer includes a substrate, a channel layer over the substrate, a barrier layer over the channel layer, and a cap layer over the barrier layer. The method also includes subliming away a region of the cap layer, within the opening in the mask layer, to form an opening in the cap layer down to a top surface of the barrier layer. The material properties of the cap layer, as compared to the barrier layer, can be relied upon to form the opening in the cap layer down to the top surface of the barrier layer using sublimation, with high selectivity. Sublimation will stop with higher precision and selectivity at the interface between the cap layer and the barrier layer, as compared to etching. Typical selectivity ratios for etching are about 20:1, and the best-reported selectivity ratios for etching are reported to be about 40:1. The selectivity ratio using sublimation, as described herein, is higher than conventional selectivity ratios of other techniques, including etching. Sublimation can be relied upon to selectively remove or etch away certain materials with atomic or near-atomic levels of precision along the interfacing barriers or transitions between different types of materials.

Examples of active devices formed on wafers using sublimation processing techniques are described herein. An example active device includes a high-electron-mobility transistor (HEMT) capable of operating with relatively high levels of power and at relatively high frequency. HEMTs are field-effect transistors including a heterojunction between two layers or regions of semiconducting materials. The heterojunction substantially confines electrons to a quantum well area. Electrons confined to the heterojunction of a HEMT can exhibit higher mobilities than those in other transistors, such as metal-oxide-semiconductor field-effect transistors (MOSFETs). The sublimation processing techniques described herein exploit the different phase properties of the material layers in HEMT devices to remove or etch away regions of certain materials with high selectivity and precision. The techniques can be relied upon to form smaller HEMT devices with higher precision.

The sublimation processing techniques and concepts described herein are not limited to the manufacture of HEMT devices. The concepts can be applied to or used with other integrated circuit devices such as, but not limited to, different types of transistors (bipolar junction transistors (BJTs), heterojunction bipolar transistors (HBTs), MOSFETs, insulated gate bipolar transistors (IGBTs), metal-insulator-semiconductor HEMTs (MISHEMTs), metal-semiconductor field-effect transistor (MESFETs), etc.), diodes, integrated capacitors, integrated inductors, microstrip transmission lines, and other circuit elements.

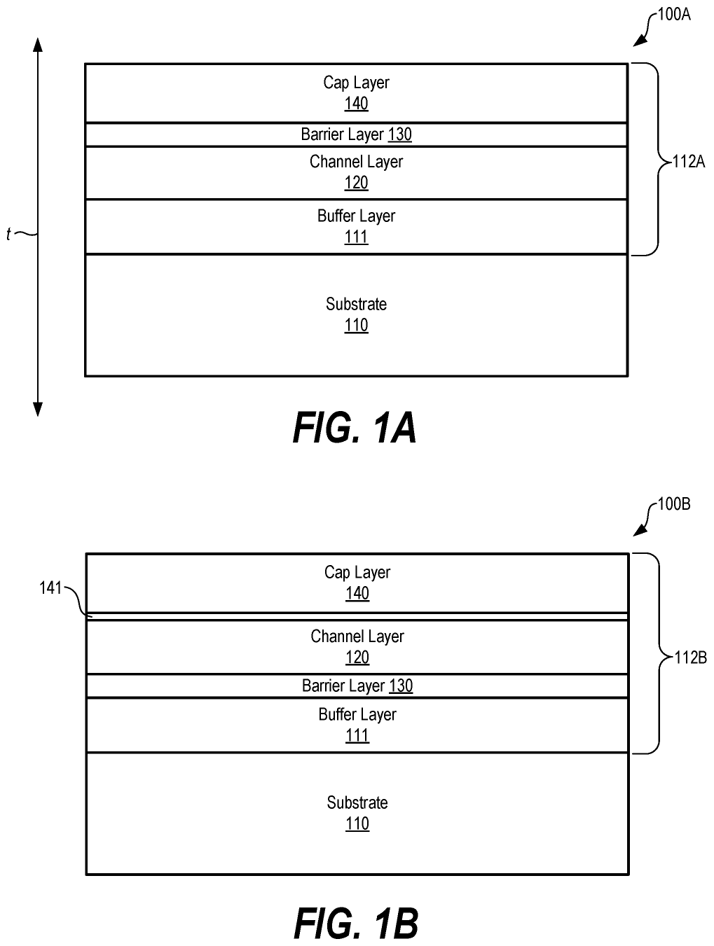

FIG. 1A illustrates a sectional view of a semiconductor material wafer 100A. The wafer 100A is illustrated as a representative example. The wafer 100A, and the layers of the wafer 100A, are not drawn to a precise scale in FIG. 1A. The thicknesses of the layers of the wafer 100A are not drawn to any particular scale, and the individual thicknesses of the layers can vary as compared to each other. Example thicknesses of the layers of the wafer 100A are described herein, although the concepts are not limited to use with layers having any particular thickness. Additionally, example materials of the wafer 100A and the individual layers of the wafer 100A are described below. However, the sublimation processing techniques and resulting devices described herein are not limited to use with any particular types of materials.

In one example, no other layers beyond those shown in FIG. 1A are relied upon or included in the wafer 100A, and the wafer 100A consists only of the layers shown in FIG. 1A and described below. In other cases, the wafer 100A can include other layers in addition to those shown in FIG. 1A. Some of the additional layers that may be included in the wafer 100A are described herein, but the description is not exhaustive of the types of layers that may be included in the wafer 100A. In other cases, one or more of the layers of the wafer 100A can be omitted.

The wafer 100A includes a substrate 110 and one or more layers 112A over the substrate 110. The substrate 110 and the layers 112A over the substrate 110 can be referred to as an epiwafer or an epiwafer substrate in some cases. An epiwafer can include a number of different layers formed over a substrate. An epiwafer can include different types or compositions of semiconductor materials in a number of different layers. The respective material compositions of the semiconductor materials, the dopants (either unintentional impurities or intentionally-added dopants) used in the layers, the arrangement of the layers, the thicknesses of the layers, and other material and structural aspects of an epiwafer all contribute to the performance characteristics of transistors and other active devices formed on the epiwafer.

The substrate 110 can be formed in any suitable way or obtained or sourced from a vendor. The substrate 110 can be between 50 mm-200 mm in diameter, although the substrate 110 can be smaller or larger in some cases. Example substrate diameters include 50 mm, 75 mm, 100 Amm, 150 mm, and 200 mm, although other sizes can be relied upon. The substrate 110 can be embodied as a bulk Si substrate in one example, although other types of substrates can be relied upon, such as bulk SiC, AlN, GaN, and other types of substrates. The sublimation processing techniques described herein can be applied to a range of sizes, shapes, and types of substrates. The techniques can also be applied to semiconductor materials and thin films of semiconductor materials supported on other types of carriers (e.g., besides semiconductor substrates).

The substrate 110 can be embodied as an intrinsic semiconductor material (e.g., undoped) or an extrinsic semiconductor material (e.g., doped with p- or n-type dopants or impurities). The substrate 110 can be embodied as a (111)-oriented Si substrate, as one example, although other types of Si substrates can be relied upon. If embodied as a SiC substrate, the substrate 110 can be a 4H—SiC polytype substrate, a 6H—SiC polytype substrate, or a 3C—SiC polytype substrate, among other types of polytype SiC substrates. In other cases, the substrate 110 can be embodied as a composite substrate, such as a substrate including one or more top layers of Si, SiC, AlN, or GaN over a substrate of another bulk type of material. The layers and substrate may be single-crystal, polycrystalline, nano-crystalline, amorphous, composite, or other form.

In some cases, the substrate 110 can be doped to have a relatively high resistivity or low conductivity. The substrate 110 can have a resistivity in a range between about 3,000 Ohm-cm to about 10⁷ Ohm-cm, including resistivities of greater than or equal to 10⁴, 10⁵, 10⁶, or 10⁷ Ohm-cm and greater than or equal to 10⁷ Ohm-cm. In other cases, the substrate 110 can be doped to have a relatively low resistivity or high conductivity, such as a resistivity of less than or equal to 0.2 Ohm-cm. The sublimation processing techniques described herein can be applied to substrates having a range of resistivities and conductivities, including those having higher resistivities or lower conductivities than the examples above and those having lower resistivities or higher conductivities than the examples above.

The layers 112A can be formed on the substrate 110 using suitable growth or deposition techniques. The layers 112A can be referenced as epitaxial layers formed on or over the substrate 110. For example, one or more of the layers 112A can be formed using a chemical vapor deposition (CVD) process. Example CVD processes include, but are not limited to, metal organic CVD (MOCVD), atmospheric pressure CVD (APCVD), low-pressure CVD (LPCVD), plasma enhanced CVD (PECVD), and ultrahigh vacuum chemical vapor deposition (UHVCVD). Other deposition processes include hydride vapor phase epitaxy (HYPE), molecular beam epitaxy (MBE) (including Gas Source MBE (GSMBE) or Plasma Assisted MBE (PAMBE)), and other techniques. One or more of the layers 112A can also be formed using atomic layer deposition (ALD) processing techniques. The layers 112A can include one or more layers of III-V semiconductor materials, III-Nitride semiconductor materials, or other types of semiconductor materials. A number of different example materials are described for each of the layers 112A below, but the concepts described herein are applicable and can be extended to other materials beyond the examples.

Examples arrangements and compositions of the layers 112A are described below and shown in the drawings. The layers 112A are described as being embodied by III-V semiconductor materials, such as III-Nitride semiconductor materials, as examples. The techniques described herein are not limited to use with the particular materials or arrangements of the layers described below and shown, however. Generally, in a semiconductor structure including two or more layers of semiconductor materials, the materials of first and second layers in the structure can be respectively selected such that the first layer will sublime away (i.e., transition from solid to gas) at a lower temperature than the second layer with high selectivity at a given pressure. The sublimation of the first layer down to, but not including, the second layer can be relied upon to selectively define features in devices formed in III-V materials, such as III-Nitride devices, according to the embodiments.

As shown in FIG. 1A, the layers 112A include a buffer layer 111, a channel or conduction layer 120 (“channel layer 120”), a barrier layer 130, and a cap layer 140. The buffer layer 111 is representative of, and can include in some cases, one or more layers for heteroepitaxy, lattice mismatch, thermal mismatch, and related concerns between the substrate 110 and the channel layer 120. As examples, the buffer layer 111 can include interface, nucleation, transition, back-barrier, and other layers for heteroepitaxy, lattice mismatch, thermal mismatch, and related concerns between the substrate 110 and the channel layer 120. Thus, the buffer layer 111 accommodates a range of electrical, crystal and material growth and purity, stress, and related concerns for the desired performance of the channel layer 120, including stress and strain requirements which can lead to wafer level warp and bow, as well as crystalline defect density reduction (e.g., threading defects). In some cases, such as if the substrate 110 is embodied as bulk GaN, the buffer layer 111 (or certain layers in the buffer layer 111), can be omitted.

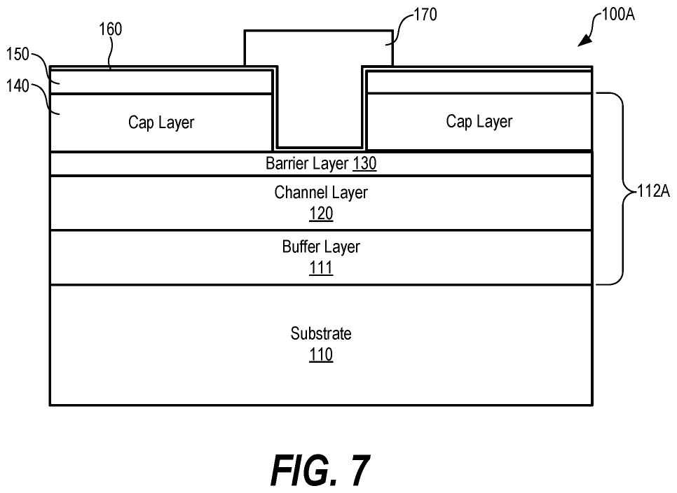

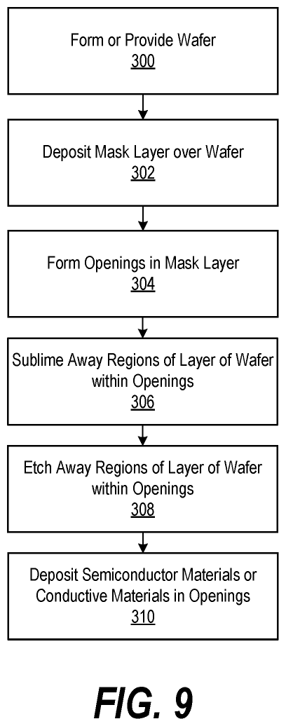

While interface, nucleation, transition, back-barrier, and other layers can be considered as part of the buffer layer 111, those of skill in the art may also recognize interface, nucleation, transition, back-barrier, and other layers as being separate layers from the buffer layer 111. Thus, the wafer 100A can also include interface, nucleation, transition, back-barrier, and other layers separate from the buffer layer 111 in some embodiments. Such layers can be positioned between the substrate 110 and the buffer layer 111 or, in some cases, between the buffer layer 111 and the channel layer 120. Examples of interface, nucleation, transition, back-barrier, and other layers are also described in U.S. patent application Ser. No. 18/001,141, filed Dec. 8, 2022, titled “SUPPRESSION OF PARASITIC ACOUSTIC WAVES IN INTEGRATED CIRCUIT DEVICES” (“the '141 Application”) the entire contents of which are incorporated herein by reference in their entirety. As a particular example, the wafer 100A can include the superlattice structures described in connection with FIGS. 7 and 9 of the '141 Application between the substrate 110 and the buffer layer 111.

The thickness of the buffer layer 111 can range from between 1000-2000 nanometers (nm), for example, although other thicknesses can be relied upon. As described herein, reference to the “thickness” of individual layers of the wafer 100A is a measurement of the cross-sectional thickness of the layer from the top surface of the layer to the bottom surface of the layer, in the direction from the top to the bottom of the page along the line “t” in FIG. 1A. Additionally, a “top” or “top surface” of a layer is positioned toward the top of the page, and a “bottom” or “bottom surface” of a layer is positioned toward the bottom of the page, below the top surface.

The buffer layer 111 can include a nucleation layer of GaN materials, such as a nucleation layer of AlN, to confine treading dislocations, lattice mismatches, and other material-transition concerns between the substrate 110 and the channel layer 120. The nucleation layer and other layers in the buffer layer 111 can also be compensation doped to be electrically insulating. The buffer layer 111 can also include a back-barrier layer to help confine the carriers in the channel layer 120. Iron or carbon, for example, can be used as dopants in the buffer layer 111 to increase resistivity in the buffer layer 111, in some cases.

The buffer layer 111 can also include one or more transition layers of GaN materials, to reduce internal stresses among the layers in the wafer 100A. The stresses can be due to lattice mismatch between the substrate 110 and the channel layer 120, from differences between the thermal expansion rates of the substrate 110 and the channel layer 120, and other factors. One or more of the transitional layers can include an impurity or dopant, such as carbon. One or more of the transitional layers can also be compositionally-graded. That is, the concentration of at least one of the elements (e.g., Ga, Al, indium (In)) in the layers can be varied across at least a portion of the thickness of the transitional layers. As one example of compositional grading, a transitional layer can have a relatively high concentration of gallium near the top surface and a relatively low concentration of gallium near the bottom surface of the transitional layer. Other layers, such as the channel layer 120 and the barrier layer 130, can also be compositionally-graded in some cases. The change in concentration of gallium can be a gradual or gradient change, a stepwise change, a repeating gradient or stepwise change, or other variation.

The channel layer 120 can be embodied as a layer of GaN or GaN materials formed over the substrate 110. The channel layer 120 can have a thickness designed to meet certain vertical, lateral, or vertical and lateral breakdown or voltage requirements of one or more transistors or other active devices formed on the wafer 100A. The thickness of the channel layer 120 can range from between 20 nm to 4 micrometers (μm), although other thicknesses can be relied upon. As particular examples, the thickness of the channel layer 120 can range from between 30-50 nm, 50-100 A nm, 100 A-200 nm, 200-400 nm, 400-800 nm, 1-2 μm, or 2-4 μm.

The channel layer 120 can be embodied as a clean (e.g., substantially without crystal defects, impurities, etc., to the extent possible) layer of unintentionally doped (UID) GaN or UID GaN materials in crystalline form in one case. It should be appreciated, however, that some impurities can be common in layers of GaN materials because it is relatively difficult (if not impossible) to exclude all impurities. As used herein, UID GaN layers and UID GaN material layers are formed using techniques without the intention to include (or with the intention to minimize to the extent possible) dopants or other impurities other than the base materials of the layers. In other cases, one or more regions of the channel layer 120 can include dopants or intentionally-added dopants to increase conductivity or for other purposes.

In the wafer 100A, the materials of the barrier layer 130 and the cap layer 140 can be respectively selected such that the cap layer 140 will sublime away (i.e., transition from solid to gas) at a lower temperature than the barrier layer 130 with high selectivity at a given pressure. As examples, the barrier layer 130 can be embodied as a layer of AlN, a layer of aluminum gallium nitride (AlGaN), or another binary or tertiary material (e.g., AlInN, AlInGaN, etc.). The materials of the barrier layer 130 can be selected, in any case, to have a sublimation characteristic that is different than that of the cap layer 140, as further described below. The thickness of the barrier layer 130 can be relatively small and selected in part based on the dimensions of the devices to be formed using the wafer 100A. The barrier layer 130 can have a thickness of less than ⅛^{th} the length of the gate channel (measured between the source and the drain) of a transistor formed using the wafer 100A. The barrier layer 130 can have a thickness of between 0.3-5 nm, or a narrower range, such as between 0.3-4 nm, between 0.3-3 nm, between 0.3-2.5 nm, between 0.3-2 nm, or narrower. In particular examples, the barrier layer 130 can have a thickness of 2 nm, 1 nm, 0.5 nm, or 0.3 nm, although other thicknesses can be relied upon.

Typical thicknesses of barrier layers used in other devices have been on the order of between 10-20 nm, 10-50 nm, and sometimes larger, and the use of thinner barrier layers has presented manufacturing challenges. The use of the sublimation processes described herein offer an approach to remove the cap layer 140 down to the top surface of the barrier layer 130, without removing the barrier layer 130, with very high precision, and enables the use of thinner barrier layers.

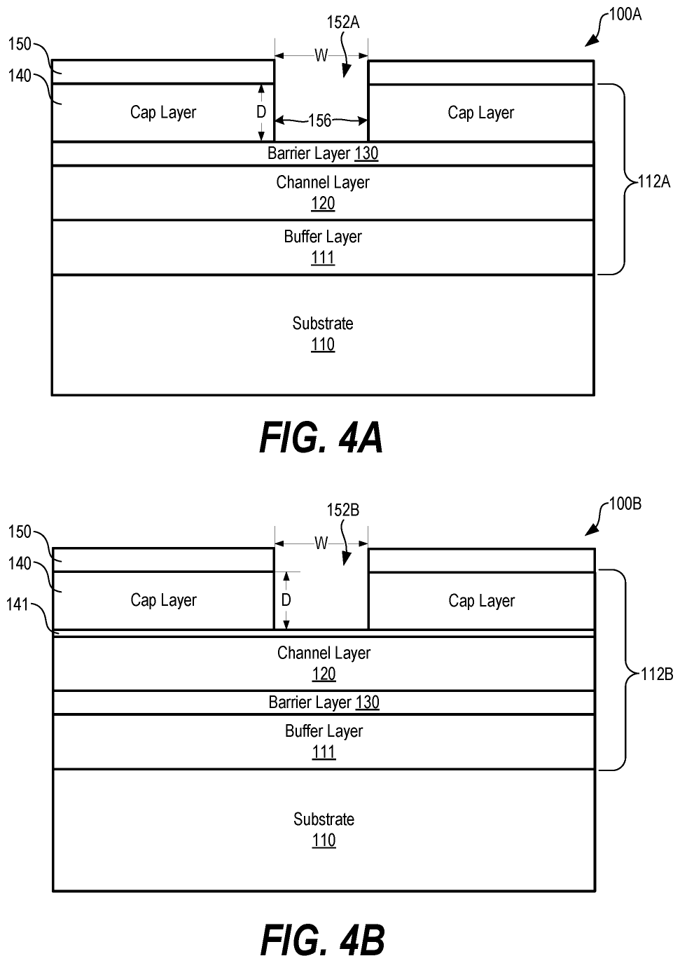

A heterojunction is formed between the channel layer 120 and the barrier layer 130, and an electron channel or two-dimensional electron gas (2DEG) is formed at the interface between the channel layer 120 and the barrier layer 130, due to polarization at the materials interface between the barrier layer 130 and the channel layer 120. In one example, the 2DEG is particularly present in a channel region near the top surface of the channel layer 120 and near the bottom surface of the barrier layer 130 based on the polarization at the interface. Thus, transistors or other active devices, such as HEMT devices, can be formed using the wafer 100A. In other cases, such as in the N-polar epiwafer shown in FIG. 1B and described below, the 2DEG can be formed at a position closer to the substrate 110, in connection with another III-nitride layer, as described below with reference to FIG. 4B.

As noted above, the barrier layer 130 can be embodied as a layer of AlGaN with a concentration of Al greater than zero (e.g., Alₓ Ga₍₁₋ₓ₎N, with x being greater than 0 and up to 1). In some cases, the barrier layer 130 can be embodied as two or more layers, such as a lower sub-barrier layer of AlN and one or more upper barrier layers of AlGaN, AlInGaN, and other materials. The ratio of Al to Ga in the upper barrier layers can range (e.g., Alₓ Ga₍₁₋ₓ₎N, with x being greater than 0 and up to 1). The use of separate sub-barrier and upper barrier layers can be relied upon to augment or tailor the heterojunction and 2DEG between the channel layer 120 and the barrier layer 130, as needed depending on the characteristics of the devices to be formed using the wafer 100A. In any case, the materials composition of the barrier layer 130 and any lower, upper, sub-barrier, etc., layers of the barrier layer 130 should be selected such that the sublimation temperature of the barrier layer 130 is higher than the cap layer 140 at a given pressure.

The cap layer 140 can be embodied as a layer of GaN or GaN materials formed over the substrate 110. One or more regions of the cap layer 140 can also include dopants or intentionally-added dopants in some cases. As one example, the cap layer 140 can be formed from a semiconductor material of the same type as the channel layer 120, although the materials compositions of the cap layer 140 and the channel layer 120 can vary as compared to each other in some cases. In any case, the cap layer 140 can be embodied by semiconductor materials that will sublime away at a lower temperature than the semiconductor materials of the barrier layer 130 at a given pressure. As one example, the cap layer 140 can be embodied as a layer of semiconductor materials without aluminum and the barrier layer 130 can be embodied as a layer of semiconductor materials with aluminum, to facilitate the sublimation of the cap layer 140 without the sublimation of the barrier layer 130 at a given temperature and pressure. Thus, the cap layer 140 can be embodied as a layer of UID GaN or UID GaN materials without aluminum and barrier layer 130 can be embodied as a layer of AlGaN with a concentration of Al greater than zero.

Overall, the materials composition of the barrier layer 130 should be selected such that the sublimation temperature of the barrier layer 130 is higher than the cap layer 140 at a given pressure. A range of different III-V and other materials for the barrier layer 130 and the cap layer 140, respectively, can be selected to maintain this decomposition criteria. Beyond those identified above, the cap layer 140 can be embodied as InN and the barrier layer 130 can be embodied as GaN, the cap layer 140 can be embodied as InGaN and the barrier layer 130 can be embodied as GaN, and the cap layer 140 can be embodied as ScAlGaN and the barrier layer 130 can be embodied as GaN. Other materials that maintain the decomposition criteria among the barrier layer 130 and the cap layer 140 that are consistent with the concepts described herein can also be relied upon.

The process described herein facilitates the use of a wider range of thicknesses for the cap layer 140, due to the very high selectivity in the sublimation of the cap layer 140 without disturbance of the barrier layer 130. The thickness of the cap layer 140 can range from a relatively thin layer, such as between 2-50 nm, to a relatively thick layer, such as between 200-1000 nm or more. Thus, the thickness of the cap layer 140 can range from 2-1000 nm or more, and even extend to thicknesses in the scale of μm.

Transistors and other active and passive devices can be formed in or on the wafer 100A. The transistors can be used in a range of different types of amplifiers and for other purposes. In one example, to form a transistor using the wafer 100A, a portion of a region of the cap layer 140 can be removed at least in part by sublimation to form an opening down to the barrier layer 130, and metal or one or more metal layers can be deposited or otherwise formed in the opening. The metal can form a gate for the transistor, to control the flow of electrons in the 2DEG in the channel layer 120, near the bottom surface of the barrier layer 130. In some cases, one or more insulating layers can be formed in the opening before the metal is deposited in the opening. In other cases, one or more layers of semiconductor materials can be deposited or grown in the opening before the metal is deposited in the opening. Thus, a range of different types of transistors can be formed, including MESFETs, MISHEMTs, and others. Additionally, other portions or regions of the cap layer 140 and the barrier layer 130 can be removed to form an opening down to (or in part into) the channel layer 120, and one or more metal layers can be used to form the drain and source of the transistor.

Particularly if the barrier layer 130 is selected to be relatively thin for the miniaturization of devices formed using the wafer 100A, it can be difficult to form an opening in the cap layer 140 precisely and without removing or damaging the surface of the barrier layer 130 (or a portion of the barrier layer 130) using etching techniques. In other words, plasma etching, reactive ion etching (RIE), deep reactive ion etching (DRIE), inductively coupled plasma (ICP) etching, or other etching techniques may not offer a suitable level of selectivity in the removal of the channel layer 120 as compared to the barrier layer 130, and it can be difficult to stop the etching process at or about the top surface of the barrier layer 130. This issue can be further complicated if the cap layer 140 is relatively thick.

According to aspects of the embodiments, the material properties of the cap layer 140 as compared to the barrier layer 130 can be selected and relied upon to form openings in the cap layer 140 using sublimation rather than etching, with higher selectivity. More particularly, the materials of the cap layer 140 and the materials of the barrier layer 130 can be respectively selected such that the cap layer 140 will sublime away at a lower temperature than the barrier layer 130, with high selectivity, at a given pressure. At 10⁻⁸ Torr, for example, a cap layer 140 of GaN will sublime away at about 750° C., whereas a barrier layer 130 of AlN is stable and will not sublime away until about 1300° C. The sublimation of GaN at low pressure, particularly at much lower temperatures than required to sublime AlN or another Al-based GaN alloy, can be relied upon to selectively define features in III-nitride devices according to the embodiments. Thus, the techniques described herein exploit the different phase properties of material layers and heterostructures in semiconductor structures, as a means to remove certain materials with high selectivity and precision (e.g., even down to the atomic scale) through sublimation.

For a cap layer 140 of GaN and a barrier layer 130 of AlN, as just one example, sublimation will stop with higher precision and fidelity (e.g., with very high and near perfect selectivity) at the interface between the cap layer 140 and the barrier layer 130, without removing the barrier layer 130, as compared to etching. Typical selectivity ratios for etching are about 20:1, and the best-reported selectivity ratios for etching are reported to be about 40:1. The selectivity ratio using sublimation is much higher than conventional selectivity ratios of many other etching and related materials removal techniques.

Thus, sublimation is relied upon to form one or more openings in the cap layer 140, down to the barrier layer 130, in one aspect of the embodiments. Sublimation can also be relied upon, at least in part, to form one or more openings in the cap layer 140 and in the barrier layer 130, in another aspect of the embodiments. Metal for electrodes can be formed or deposited in the openings after sublimation is used to create the openings. In some cases, one or more insulating layers, regrown GaN material layers, or other layers can be formed over the wafer 100A and into the openings, before the metal electrode is formed. The use of sublimation can also be incorporated with other process steps, including etching and regrowth of GaN materials, to form ohmic contacts for one or more active devices using the wafer 100A in a number of ways.

Examples of the use of sublimation to form one or more openings in the cap layer 140, down to the barrier layer 130, in the wafer 100A are described below. The concepts are also applicable to other types of epiwafers, however, such as in epiwafers including N-polar nitride heterostructures. Thus, the examples described below also include the use of sublimation to form openings in one or more layers of other types of wafers including layers and heterostructures that differ from the wafer 100A.

As another example epiwafer, FIG. 1B illustrates a sectional view of another semiconductor material wafer 100B according to aspects of the embodiments. The wafer 100B is illustrated as a representative example. The wafer 100B, and the layers of the wafer 100B, are not drawn to a precise scale in FIG. 1B. The thicknesses of the layers of the wafer 100B are not drawn to any particular scale, and the individual thicknesses of the layers can vary as compared to each other.

The wafer 100B includes a substrate 110 and one or more layers 112B over the substrate 110. The substrate 110 and the layers 112B over the substrate 110 can be referred to as an epiwafer or an epiwafer substrate. The layers 112B of the wafer 100B shown in FIG. 1A are similar to the layers 112A of the wafer 100A shown in FIG. 1B, and any layer in the wafer 100B that shares the same reference numeral as that in the wafer 100A can have the same or similar material composition, thickness, and characteristics as the corresponding layer in the wafer 100A.

One difference between the wafer 100A shown in FIG. 1A and the wafer 100B shown in FIG. 1B is that the positions of the channel layer 120 and the barrier layer 130 are reversed as compared to each other. That is, in FIG. 1B, the channel layer 120 is formed over the barrier layer 130. As understood in the field, the wafer 100A is an example of a gallium-polar (Ga-polar) epiwafer, and the wafer 100B is an example of a nitrogen-polar (N-polar) epiwafer. A heterojunction is formed in the wafer 100B between the channel layer 120 and the barrier layer 130. A 2DEG region is formed at the interface between the channel layer 120 and the barrier layer 130 in the wafer 100B. However, as compared to the wafer 100A, the 2DEG region in the wafer 100B is formed in a channel region near the bottom surface of the channel layer 120 and the top surface of the barrier layer 130, at a position closer to the substrate 110.

Another difference between the wafer 100A shown in FIG. 1A and the wafer 100B shown in FIG. 1B is that the wafer 100B includes a stop layer 141. The stop layer 141 is positioned between the cap layer 140 and the channel layer 120. The stop layer 141 can be formed as a relatively thin layer of GaN materials including a concentration of Al greater than zero (e.g., AlₓGa₍₁₋ₓ₎N, with x being greater than 0). The thickness of the stop layer 141 can range from between 2-50 nm, for example, although other thicknesses can be relied upon. In some cases, the stop layer 141 can be formed as a lower layer or region of the cap layer 140. The cap layer 140 (or remainder of the cap layer 140), in any case, is preferably embodied as a layer of semiconductor materials without aluminum, to facilitate the sublimation of the cap layer 140 away according to the embodiments. The stop layer 141 can be relied upon to halt or stop the sublimation of the cap layer 140 according to the concepts described herein.

Manufacturing N-polar devices with precise and repeatable threshold voltages has been relatively challenging using conventional etching techniques. The selectivity of conventional etching techniques has not been high enough to stop on the stop layer 141 in a repeatable and precise way to control the threshold voltage of N-polar devices. The sublimation processing techniques described herein can be applied to achieve higher stop selectivity on the stop layer 141 and better control of the threshold voltage of N-polar devices.

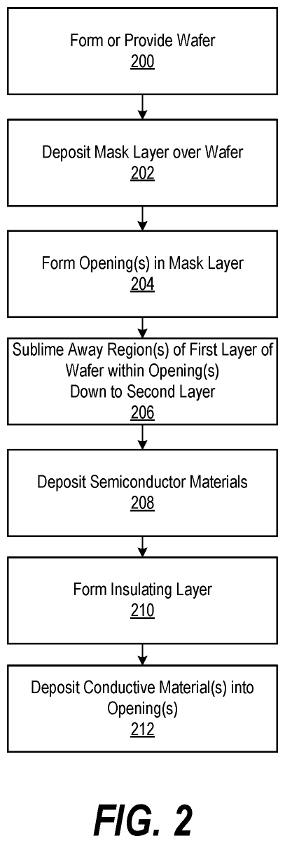

FIG. 2 illustrates a process for the manufacture of semiconductor structures using sublimation according to aspects of the embodiments. The process steps shown in FIG. 2 are provided as a representative example. FIG. 2 is not exhaustive, as other process steps can be included. Additionally, in some cases, one or more of the process steps shown in FIG. 2 can be omitted, and the arrangement of the steps can be altered or rearranged as compared to that shown. The process shown in FIG. 2 can be applied to a range of different wafers or epiwafers. Thus, while the process shown in FIG. 2 is described in connection with the wafer 100A shown in FIG. 1A and the wafer 100B shown in FIG. 2A, the process can be applied to other types of wafers, including wafers having layers similar to, but in some cases different than, those in the wafers 100A and 100B. The process steps shown in FIG. 2 can also be combined with other process steps, such as those shown in FIG. 9 and described below, to manufacture transistors and other active semiconductor devices.

At step 200, the process includes forming or providing a wafer or epiwafer. As examples, the process can include forming or providing the wafer 100A shown in FIG. 1A or the wafer 100B shown in FIG. 1B. As described above, the wafer 100A can include a substrate 110 and a number of layers 112A formed over the substrate 110. The layers 112A can be formed on the substrate 110 using suitable semiconductor materials growth or deposition techniques at step 200. For example, one or more of the layers 112A can be formed using deposition (e.g., CVD, MOCVD, APCVD, LPCVD, PECVD, UHVCVD, ALD, etc.), epitaxy (e.g., HVPE, MBE, GSMBE, PAMBE, etc.), or other techniques or combinations thereof. The layers 112B of the wafer 100B can also be formed over the substrate 110 in a similar way.

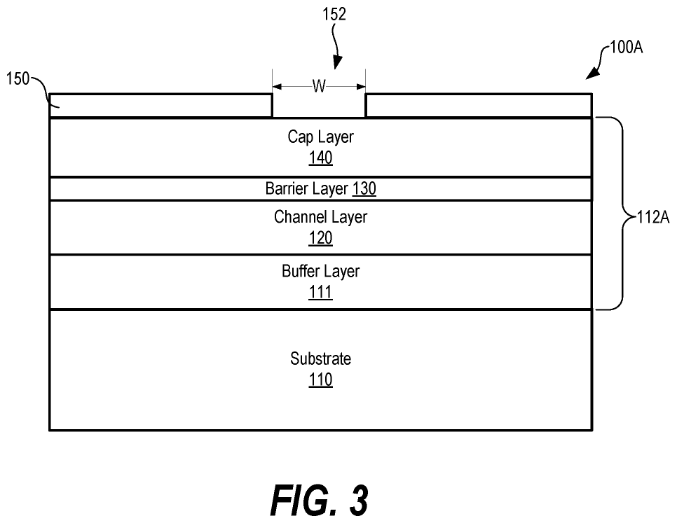

At step 202, the process includes depositing a mask layer or mask over the wafer that was formed or provided at step 200. Referring to FIG. 3 as an example, a mask layer 150 can be deposited or otherwise formed over the cap layer 140 of the wafer 100A at step 202. As another example, the mask layer 150 can be deposited or otherwise formed over the cap layer 140 of the wafer 100B at step 202. The mask layer 150 can be embodied as an electrically-insulating dielectric layer, such as a dielectric layer of silicon dioxide (SiO₂), silicon nitride (SiN), aluminum oxide, or other dielectric insulator (e.g., silicon oxide, hafnium oxide, lanthanum oxide, titanium oxide, zinc oxide, zirconium oxide, gallium oxide, scandium oxide, aluminum nitride, hafnium nitride, etc.). In other examples, the mask layer 150 can be a metal layer or any other suitable material common in semiconductor processing which can withstand the sublimation atmosphere needed to sublime the cap layer 140. The mask layer 150 can also be embodied as two or more layers, such as a dielectric insulating layer over a metal layer. The mask layer 150 can be formed or deposited using any suitable materials deposition techniques.

In some cases, the mask layer 150 can be deposited over the cap layer 140 of the wafers 100A and 100B during or as part of the same steps used to provide the wafers 100A and 100B at step 200. In other words, the mask layer 150 can also be deposited over the cap layer 140, in situ, as part of the process steps used to deposit the layers 112A and 112B over the substrate 110, after the layers 112A and 112B are deposited. In that case, the wafer provided at step 200 can include the mask layer 150, and step 202 can be omitted or skipped.

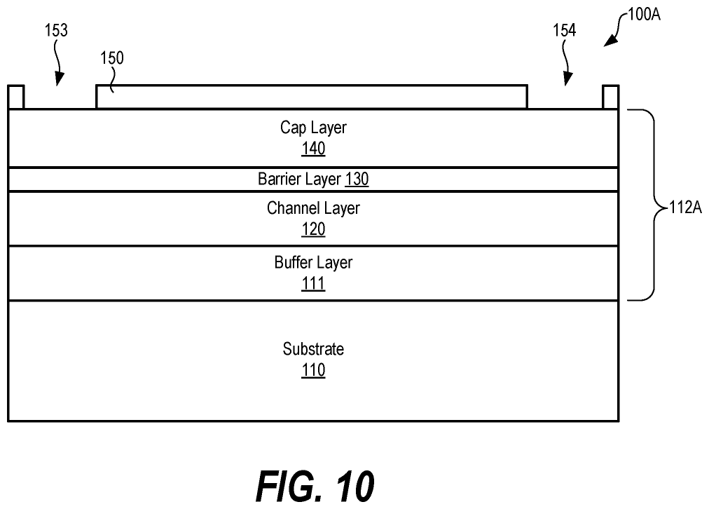

At step 204, the process includes forming one or more openings through the mask layer. Referring again to FIG. 3 as an example, the process can include forming the opening 152 in the mask layer 150 at step 204. The opening 152 through the mask layer 150 can be formed using photolithography, such as by applying a photoresist layer over the mask layer 150, patterning the photoresist layer, and selectively removing the photoresist layer and the mask layer 150 in the region of the opening 152. A region of the cap layer 140 is exposed through the mask layer 150, in the opening 152. In some cases, the cap layer 140 can be damaged, partly etched away, or both during step 204, particularly in the area within the opening 152. Such damaged or partly etched areas or regions of the cap layer 140 can be removed in step 206, as described below. In other cases, two or more openings can be formed through the mask layer 150. Examples of forming more than one opening through the mask layer are described below with reference to FIG. 10.

The opening 152 is illustrated as a representative example in FIG. 3. The position, width “W,” and other characteristics of the opening 152 can vary depending on the type and size of the device being manufactured, among other factors. Additionally, step 204 can also include forming a number of openings through a mask layer, such as a number of openings through the mask layer 150. Additional examples in which openings are formed at different locations and in which multiple openings are formed through the mask layer 150 are also described below.

At step 206 in FIG. 2, the process includes subliming away a region of a first layer of the wafer provided at step 200 down to the top surface of a second layer of the wafer. Referring to FIG. 4A as an example, step 206 can include subliming away a region of the cap layer 140 of the wafer 100A, within and below the opening 152 in the mask (see FIG. 3), down to a top surface of the barrier layer 130. The opening or trench 152A (“opening 152A”) shown in FIG. 4A is formed at step 206 through sublimation, as described herein. The opening 152A extends from a top surface of the cap layer 140, through the cap layer 140, and down to a top surface of the barrier layer 130. The opening 152A is also positioned below the opening 152 in the mask layer 150. The opening 152A can be referred to herein as a sublimed opening.

For the sublimation at step 206, the wafer 100A and mask layer 150 can be placed into a chamber (if not already within the chamber as part of previous steps) capable of providing a vacuum environment over a range of temperatures and pressures. For example, the wafer 100A can be placed into the chamber of a Molecular-Beam Epitaxy (MBE) tool, although other tools or chambers can be relied upon. The wafer 100A can be exposed to a vacuum at one or more pressures (e.g., measured in Torr) within a pressure range and one or more temperatures within a temperature range in the chamber, to provide an environment in which the exposed cap layer 140 will sublime away (i.e., experience a phase change from the solid to gaseous phase).

The GaN materials in the cap layer 140 will begin to sublime away at and above a minimum sublimation temperature of the GaN materials associated with a given pressure in the chamber. The minimum sublimation temperature for GaN materials is a function of the pressure in the chamber. At a pressure of 10⁻⁸ Torr and >750° C., for example, GaN materials in the cap layer 140 will sublime away. Thus, subliming a region of the cap layer 140 to form the opening 152A can include evacuating the atmosphere in the chamber to a level of equal to or greater than 10⁻⁸ Torr and raising the temperature in the chamber to equal to or greater than 750° C., although other pressures and other temperatures (and particularly higher temperatures, e.g., equal to or greater than 800° C. but less than or equal to 1200° C.) can be relied upon for sublimation.

Sublimation can be performed at any temperature above the minimum temperature for sublimation of the GaN materials in the cap layer 140, for a given pressure in the chamber. Overall, at a given temperature, the GaN materials in the cap layer 140 will sublime away, if at all, more quickly or easily at relatively lower pressures. At the same given temperature, the GaN materials in the cap layer 140 will sublime away, if at all, less quickly or easily at relatively higher pressures. Similarly, at a given pressure, the GaN materials in the cap layer 140 will sublime away, if at all, more quickly or easily at relatively higher temperatures. At the same given pressure, the GaN materials in the cap layer 140 will sublime away, if at all, less quickly or easily at relatively lower temperatures. Sublimation can be performed at lower temperatures for lower pressures, at any temperature above the minimum temperature for sublimation for a given pressure.

The exposed GaN materials in the cap layer 140 will transition from the solid to gaseous phase over time under the conditions described above, among others, to form the opening 152A. The GaN materials in the cap layer 140 will also sublime away over a range of temperatures and vacuum conditions, and other temperatures and levels or vacuum can be used. The temperature and vacuum settings should preferably be selected, in any case, to avoid the sublimation of the barrier layer 130. AlN in the barrier layer 130 will not sublime away until about 1300° C., even at a pressure of about 10⁻⁸ Torr. AlGaN and other compositions of binary or tertiary materials (e.g., AlInN or AlInGaN) in the barrier layer 130 also will not sublime away until much higher temperatures than GaN at a given pressure, depending on the particular compositions (e.g., the In content) of the materials. Similarly, the SiO₂ or other material of the mask layer 150 also will not sublime away under the same conditions as the cap layer 140.

Overall, the processing window for the sublimation of the GaN materials in the cap layer 140, without sublimation of the AlN in the barrier layer 130, is large enough to stop or halt the opening 152A from extending into the barrier layer 130 over a suitable temperature and pressure processing range. The opening 152A in the cap layer 140 stops at the barrier layer 130 with high precision, even if the conditions for sublimation of the cap layer 140 are maintained in the chamber after the top surface of the barrier layer 130 is exposed.

As noted above, step 206 includes subliming away a region of a first layer of the wafer provided at step 200 down to the top surface of a second layer of the wafer. The sublimation at step 206 facilitates both the use of a relatively thicker first layer and a relatively thinner second layer in the wafer being processed. For example, typical thicknesses of barrier layers in wafers used to form transistors have been on the order of between 10-20 nm, 10-50 nm, and sometimes larger, and the use of thinner barrier layers has presented manufacturing challenges. The use of sublimation at step 206 offers an approach to remove the cap layer 140 down to the top surface of the barrier layer 130, without removing the barrier layer 130, with very high precision, and enables the use of a thinner barrier layer 130. At the same time, the sublimation permits the use of a wider range of thicknesses for the cap layer 140, due to the very high selectivity in the sublimation of the cap layer 140 without disturbance of the barrier layer 130.

The illustration of the opening 152A is representative in FIG. 4A. The sidewalls 156 of the opening 152A in the cap layer 140 may include an undercut below the mask layer 150 in some cases. The sidewalls of the opening 152A in the cap layer 140 may be shaped as ramps (rather than as dovetails), extending from the barrier layer 130 (or the bottom surface of the cap layer 140) to the top surface of the cap layer 140. The size of the opening 152A can be tailored or determined based on the width “W” of the opening in the mask layer 150 and the thickness of the cap layer 140. The depth “D” of the opening 152A is the same or substantially the same as the thickness of the cap layer 140.

An aspect ratio of the opening 152A can be defined as a ratio of the depth “D” of the trench or opening 152A to the width “W” of the trench or opening 152A (i.e., “D”/“W”). The aspect ratio can be greater than or equal to 1 in many cases, but the aspect ratio can also be less than 1. The aspect ratio of the opening 152A can vary, for example, depending on the type and desired electrical characteristics of the active device or devices being formed using the wafer 100A. Overall, sublimation can be relied upon to increase the aspect ratio of the opening 152A (i.e., increase “D,” reduce “W,” or both increase “D” and reduce “W”) with better precision and results as compared to plasma, RIE, DRIE, and other etching techniques.

As another dimensional factor, a scale ratio can be defined as a ratio of the width “W” of the opening 152A to the thickness of the barrier layer 130. This scale ratio can be maintained or increased for transistors having reduced gate lengths according to the embodiments. In that context, “W” corresponds to the length of the gate of a transistor formed using the wafer 100A. The thickness of the barrier layer 130 can be reduced when using sublimation to form the opening 152A as compared to other techniques. Thus, even when “W” is scaled down (i.e., reduced in size), the scale ratio can be maintained or increased for transistors having reduced gate lengths because the thickness of the barrier layer 130 can also be reduced.

As another example, referring to FIG. 4B, step 206 can include subliming away a region of the cap layer 140 of the wafer 100B, within an opening in the mask layer 150, down to a top surface of the stop layer 141. The opening 152A shown in FIG. 4B is formed at step 206 through sublimation, as described herein. The opening 152A extends from a top surface of the cap layer 140, through the cap layer 140, and down to a top surface of the stop layer 141.

For the sublimation at step 206, the wafer 100B and mask layer 150 can be placed into a chamber (if not already within the chamber as part of previous steps) capable of providing a vacuum environment over a range of temperatures and pressures. The wafer 100B can be placed into the chamber of an MBE tool, although other tools or chambers can be relied upon. The wafer 100B can be exposed to a vacuum at one or more pressures (e.g., measured in Torr) within a pressure range and one or more temperatures within a temperature range in the chamber, to provide an environment in which the exposed cap layer 140 will sublime away (i.e., experience a phase change from the solid to gaseous phase).

The temperature and vacuum settings should preferably be selected, in any case, to avoid the sublimation of the stop layer 141. Because it includes aluminum, the stop layer 141 will not sublime away until about 1300° C., even at a pressure of about 10⁻⁸ Torr. AlGaN and other compositions of binary or tertiary materials (e.g., AlInN or AlInGaN) in the stop layer 141 also will not sublime away until much higher temperatures than GaN at a given pressure, depending on the particular compositions (e.g., the In content) of the materials. Similarly, the SiO₂ or other material of the mask layer 150 also will not sublime away under the same conditions as the cap layer 140.

Overall, the processing window for the sublimation of the GaN materials in the cap layer 140, without sublimation of the stop layer 141, is large enough to stop or halt the opening 152A from extending into the channel layer 120 over a suitable temperature and pressure processing range. The opening 152A in the cap layer 140 stops at the stop layer 141 with high precision, even if the conditions for sublimation of the cap layer 140 are maintained in the chamber after the top surface of the stop layer 141 is exposed.

The illustration of the opening 152B is representative in FIG. 4B. The sidewalls of the opening 152B in the cap layer 140 may include an undercut below the mask layer 150 in some cases. The sidewalls of the opening 152B in the cap layer 140 may be shaped as ramps, extending from the stop layer 141 to the top surface of the cap layer 140. The size of the opening 152B can be tailored or determined based on the width “W” of the opening in the mask layer 150 and the thickness of the cap layer 140. The depth “D” of the opening 152B is the same or substantially the same as the thickness of the cap layer 140. An aspect ratio of the opening 152B can be defined as the depth “D” of the trench or opening 152B to the width “W” of the trench or opening 152B. The aspect ratio can be greater than or equal to 1 in many cases, but the aspect ratio can also be less than 1. The aspect ratio of the opening 152B can vary, for example, depending on the type and desired electrical characteristics of the active device or devices being formed using the wafer 100B.

The process can end in some cases after the sublimation at step 206. For example, the wafer 100A or the wafer 100B can be removed from the chamber in which sublimation occurred, and it is not necessary in all cases to continue with the remaining steps illustrated in FIG. 2. However, in other cases, one or more additional process steps can occur in situ (e.g., in the same chamber in which sublimation occurred) after step 206. In other cases, the wafer 100A or the wafer 100B can be removed from the chamber in which sublimation occurred and one or more additional process steps can be performed in or with one or more other processing tools.

At step 208, the process shown in FIG. 2 can also include depositing semiconductor materials, such as one or more layers of semiconductor materials. For example, at step 208, the process can include depositing or forming a regrowth or recap layer of GaN materials over the wafer 100A, in situ, in the same chamber used for sublimation (and without the vacuum being broken). As another example, step 208 can include depositing or forming a layer of GaN materials over the wafer 100B, in situ, in the same chamber used for sublimation. The environment in the chamber can be adjusted to deposit or grow rather than sublime GaN materials, by changing the pressure, changing the temperature, or changing the pressure and temperature in the chamber and, in some cases, changing or altering the ambient source material flux in the chamber. Step 208 can also be performed ex situ in some cases. That is, the deposit of semiconductor materials can be performed in a different chamber or semiconductor materials processing tool than that used for sublimation in some cases.

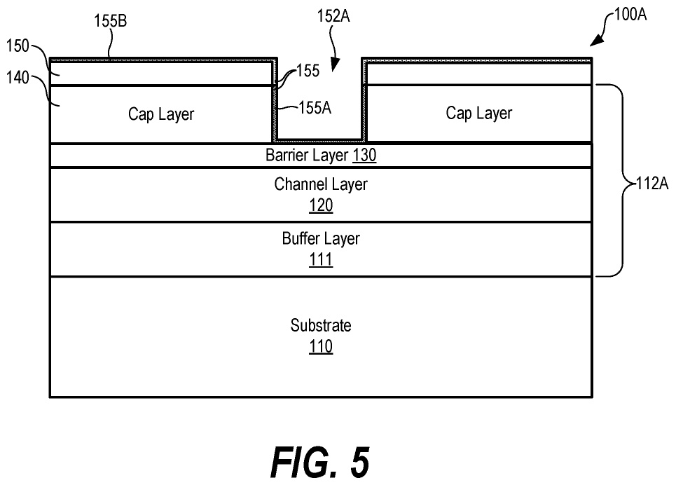

As an example of step 208, FIG. 5 illustrates a sectional view of the wafer 100A shown in FIG. 4 with a regrowth or recap layer 155 (“recap layer 155”) of semiconductor materials formed on the top surface of the barrier layer 130 within the opening 152A. The recap layer 155 of GaN materials can be deposited over the top surface of the barrier layer 130 within the opening 152A at step 208 to the extent (e.g., thickness) needed or desired depending on the desired characteristics of the device being formed. A similar recap layer can also be deposited over the top surface of the stop layer 141 within the opening 152B (see FIG. 4B). The recap layer 155 can be doped or highly-doped, when regrown, to form a degenerate recap layer.

The recap layer 155 can include a first recap layer region 155A having a single crystal structure over the barrier layer 130 and between the exposed sidewalls of the cap layer 140 within the opening 152A. The recap layer 155 can also include a second recap layer region 155B having a polycrystal structure over the mask layer 150. The second recap layer region 155B can be removed by liftoff of the mask layer 150, leaving the first recap layer region 155A within the opening 152A. Alternatively, due to the polycrystal structure of the second recap layer region 155B, the second recap layer region 155B can be selectively removed without removing the mask layer 150. Step 208 can also be omitted or skipped in some cases.

The semiconductor materials regrown at step 208 can include a layer of GaN materials, such as a layer of undoped or doped GaN, a layer of undoped or doped AlGaN, a layer of undoped or doped AlN, or another layer of undoped or doped GaN materials. When the wafer 100A is used to form a transistor as part of the process shown in FIG. 2, the threshold voltage of the transistor can be tuned or controlled based on the regrowth of semiconductor materials at step 208, to form a range of enhancement-mode and depletion-mode field effect transistors. Similarly, when the wafer 100B is used to form a transistor as part of the process shown in FIG. 2, the threshold voltage of the transistor can be tuned or controlled based on the regrowth of semiconductor materials at step 208.

At step 210, the process shown in FIG. 2 can also include forming an insulating layer. For example, at step 210, the process can include forming an insulating layer over the wafer 100A, in situ, in the same chamber used for sublimation (and without the vacuum being broken). As another example, step 210 can include forming an insulating layer over the wafer 100B, in situ, in the same chamber used for sublimation. The environment in the chamber can be adjusted to grow the insulating layer, by changing the pressure, changing the temperature, or changing the pressure and temperature in the chamber and, in some cases, changing or altering the ambient source material flux in the chamber. Step 210 can also be performed ex situ in some cases. That is, growth of the insulating layer can be performed in a different chamber or semiconductor materials processing tool than that used for sublimation in some cases.

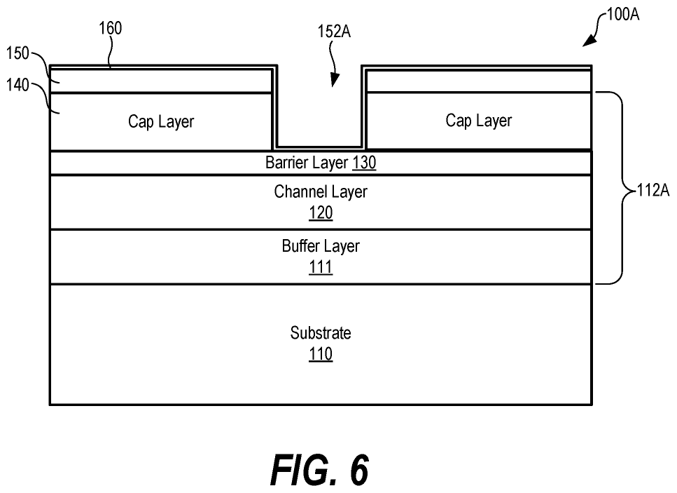

FIG. 6 illustrates a sectional view of the wafer 100A shown in FIG. 4 with an insulating layer 160 according to aspects of the embodiments. The insulating layer 160 can cover the top surface of the barrier layer 130, the sidewalls of the cap layer 140 in the opening 152A, and the top surface of the mask layer 150. The insulating layer 160 can be embodied as a thin layer of SiN, gallium oxide (Ga₂O₃), aluminum oxide, or other dielectric insulator (e.g., SiO₂, silicon oxide, etc.) in the range of tens to hundreds of Angstroms (Å) in thickness. The insulating layer 160 can be formed in situ using silicon, nitrogen, and other plasma sources, for example, or the wafer 100A can be transferred in a cluster tool to another chamber for ex situ processing. Step 210 can also include forming an insulating layer, similar to or the same as the insulating layer 160, in the opening 152B in the cap layer 140 of the wafer 100B shown in FIG. 4B. The insulating layer 160 can cover the top surface of the stop layer 141, the sidewalls of the cap layer 140 in the opening 152B, and the top surface of the mask layer 150.

The insulating layer 160 can be used to protect the wafer 100A or the wafer 100B before it is exposed to atmosphere outside (or within) the chamber, for example, or for other reasons. The insulating layer 160 can also provide an insulator between the gate of a transistor and the remaining structure of the wafers 100A or 100B when a transistor is formed using the wafers. The insulating layer 160 and any steps needed to form the insulating layer 160 can also be omitted or skipped in some cases. In other cases, the insulating layer 160 can be formed over the recap layer 155 of GaN materials described above.

Referring again to FIG. 2, at step 212, the process can also include depositing one or more types of conductive materials into the opening formed at step 204. As one example, FIG. 7 illustrates a sectional view of the wafer 100A shown in FIG. 6 with conductive materials 170 deposited into in the opening 152A (see FIG. 6). Here, step 212 can include depositing one or more layers of metal, silicide, or other types of conductive materials into the opening 152A and, in part, over the mask layer 150. As another example, step 212 can include depositing one or more layers of metal, silicide, or other types of conductive materials into the opening 152B of the wafer 100B. The conductive materials 170 can be formed and patterned using any suitable photolithographic and metal deposition or growth techniques. The conductive materials 170 can form a gate of a transistor, such as a HEMT, to control the flow of electrons in the 2DEG at the interface between the channel layer 120 and the barrier layer 130. The conductive materials 170 are formed as a type of “T” gate in FIG. 7, although other types of gate contacts can be formed. The conductive materials 170 can also form a gate and a gate-connected field plate of a transistor. The conductive materials 170 are also not limited to use as a gate, however, as the conductive materials 170 can also form an electrode or contact for other types of active devices besides transistors.

The conductive materials 170 can include one or more layers of metals or metal alloys, such as titanium (Ti), nickel (Ni), chromium (Cr), platinum (Pt), palladium (Pd), osmium (Os), Al, gold (Au), tungsten (W), rhenium (Re), tantalum (Ta), and alloys thereof. The conductive materials 170 can be formed as a multi-layer structure for a gate such as, but not limited to, Ni/Pd/Au/Ti, Ni/Pt/Au/Ti, Ni/Ti/Al/W, Ni/W/Al/W, Ni/Ta/Al/Ta, Ni/Ta/Al/W, Ni/nickel oxide (NiO)/Al/W, Ni/NiO/Ta/Al/Ta, Ni/NiO/Ta/Al/W, W/Al/W, Ni/WN/Al/W, Ni/NiO/W/Al/W, Ni/NiO/WN/Al/W, WN/Al/W, or Pt/Au/Ti multi-layer structures or compositions. In some cases, the conductive materials 170 can include one or more layers of silicides, such as platinum silicide, tungsten silicide, nickel silicide, cobalt silicide, titanium silicide, molybdenum silicide, and tantalum silicide. The conductive materials 170 can be formed by a physical deposition process (e.g., electron-beam deposition, sputtering, or plating process). The wafer 100A or the wafer 100B can be removed from the chamber used in any of steps 206, 208, and 210, and placed into a physical deposition tool for step 212 in some cases.

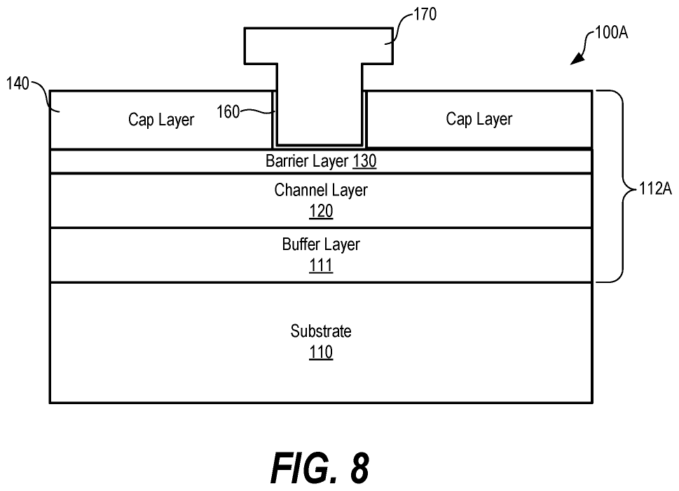

Step 212 can also include removing part of the mask layer and the insulating layer in some cases. For example, as shown in FIG. 8, the mask layer 150 and a portion of the insulating layer 160 are removed from the wafer 100A, and the same steps can be performed on the wafer 100B. As shown in FIG. 8, the conductive materials 170 have a standoff to help reduce gate parasitic capacitance. Passivation and other layers can also be formed over and around the layer 170.

Additional processing steps can also be performed before, after, or both before and after the steps shown in FIG. 2, to form other features of transistors and other active devices. For example, certain steps can be taken to prepare drain and source ohmic contact regions in the wafers 100A and 100B, either before or after sublimation is used to open the region in the cap layer 140 for the gate. In other cases, sublimation can be used to form openings for gate, drain, and source ohmic contact regions in the wafers 100A and 100B as part of a single processing step. Examples of these processing steps are described below.

FIG. 9 illustrates additional process steps for the manufacture of semiconductor structures according to aspects of the embodiments. The process steps shown in FIG. 9 are provided as a representative example. FIG. 9 is not exhaustive, as other process steps can be included. Additionally, in some cases, one or more of the process steps shown in FIG. 9 can be omitted, and the arrangement of the steps can be altered or rearranged as compared to that shown. The process steps shown in FIG. 9 can be performed without performing those shown in FIG. 2. In other cases, the process steps shown in FIG. 9 can be performed before either before or after those shown in FIG. 2. In still other cases, one or more of the process steps shown in FIGS. 2 and 9 can be combined into one or more combined steps of a process flow. Among FIGS. 2 and 9, certain overlapping steps can be combined, certain steps omitted or skipped, and other changes made as needed.

In FIG. 9, step 300 can be the same as or similar to step 200 shown in FIG. 2. At step 300, the process includes forming or providing a wafer or epiwafer. As examples, the process can include forming or providing the wafer 100A shown in FIG. 1A or the wafer 100B shown in FIG. 1B. Step 302 in FIG. 9 can also be the same as or similar to step 202 shown in FIG. 2. At step 302, the process includes depositing a mask layer or mask over the wafer that was formed or provided at step 300. Referring to FIG. 10 as an example, a mask layer 150 can be deposited or otherwise formed over the cap layer 140 of the wafer 100A at step 302. As another example, the mask layer 150 can be deposited or otherwise formed over the cap layer 140 of the wafer 100B at step 302. In other cases, the mask layer 150 can be deposited over the cap layer 140 of the wafers 100A and 100B during or as part of the same steps used to provide the wafers 100A and 100B at step 300. In that case, the wafer provided at step 300 can include the mask layer 150, and step 302 can be omitted or skipped.

At step 304 in FIG. 9, the process includes forming openings through the mask layer. Referring again to FIG. 10, the process can include forming the openings 153 and 154 in the mask layer 150 at step 304. The openings 153 and 154 through the mask layer 150 can be formed using photolithography, such as by applying a photoresist layer over the mask layer 150, patterning the photoresist layer, and selectively removing the photoresist layer and the mask layer 150 in the regions of the openings 153 and 154. Regions of the cap layer 140 are exposed through the mask layer 150, in the openings 153 and 154. The openings 153 and 154 are illustrated as representative examples in FIG. 10. The position, width, and other characteristics of the openings 153 and 154 can vary depending on the type and size of the device being manufactured, among other factors.

At step 306 in FIG. 9, the process includes subliming away regions of one or more layers of the wafer provided at step 300. As one example, step 306 can include subliming away regions of the cap layer 140 of the wafer 100A, within and below the openings 153 and 154 in the mask layer 150, as shown in FIG. 10, down to a top surface of the barrier layer 130. The sublimation technique used at step 306 in FIG. 9 can be the same as or similar to that described above at step 206 in FIG. 2.

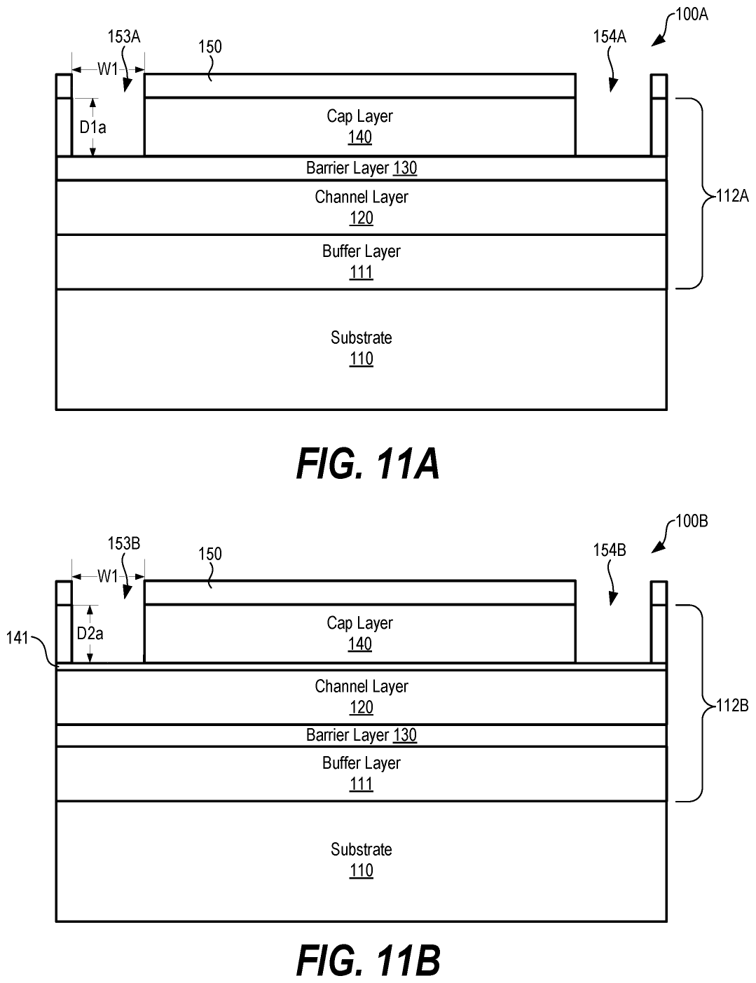

Referring to FIG. 11A for an example with the wafer 100A, sublimation at step 306 can be relied upon to form the openings 153A and 154A through the cap layer 140 and down to a top surface of the barrier layer 130, where the sublimation will selectively stop at the top surface of the barrier layer 130. The illustration of the openings 153A and 154A is representative in FIG. 11A. The sidewalls of the openings 153A and 154A in the cap layer 140 may include an undercut below the mask layer 150 in some cases. The sidewalls of the openings 153A and 154A in the cap layer 140 may be shaped as ramps (rather than as dovetails), extending from the barrier layer 130 (or the bottom surface of the cap layer 140) to the top surface of the cap layer 140. The size of the opening 153A can be tailored or determined based on the width “W1” of the opening in the mask layer 150 and the thickness of the cap layer 140. The depth “D1a” of the opening 153A is the same or substantially the same as the thickness of the cap layer 140, after step 306 is complete. The dimensions of the opening 154A can also be tailored or determined in a similar way.

Referring to FIG. 11B for an example with the wafer 100B, sublimation at step 306 can be relied upon to form the openings 153B and 154B through the cap layer 140 and down to a top surface of the stop layer 141, where the sublimation will selectively stop at the top surface of the stop layer 141. The illustration of the openings 153B and 154B is representative in FIG. 11B. The size of the opening 153B can be tailored or determined based on the width “W1” of the opening in the mask layer 150 and the thickness of the cap layer 140. The depth “D2a” of the opening 153B is the same or substantially the same as the thickness of the cap layer 140, after step 306 is complete. The dimensions of the opening 154B can also be tailored or determined in a similar way.

In some cases, the processes shown in FIGS. 2 and 9 can be combined, and the sublimation at step 306 in FIG. 9 can be performed at the same time (e.g., concurrently) as the sublimation at step 206 in FIG. 2. In that case, sublimation can be used, at least in part, to form openings for the gate, the drain, and the source of a transistor at the same time. Additional examples of combinations of the processes shown in FIGS. 2 and 9 are described below.

Notably, the sublimation performed at step 306 does not extend to the channel layer 120 of the wafer 100A or the wafer 100B. That is, the openings 153A and 154A in FIG. 11A do not extend through the barrier layer 130 to the channel layer 120. Similarly, the openings 153B and 154B in FIG. 11B do not extend through the step layer 141 to the channel layer 120. Without access to the channel layer 120, the openings 153A, 154A, 153B, 154B cannot be used to form ohmic drain and source contacts. As such, step 308 includes an additional etching process to extend the depths of the openings 153A, 154A, 153B, 154B.

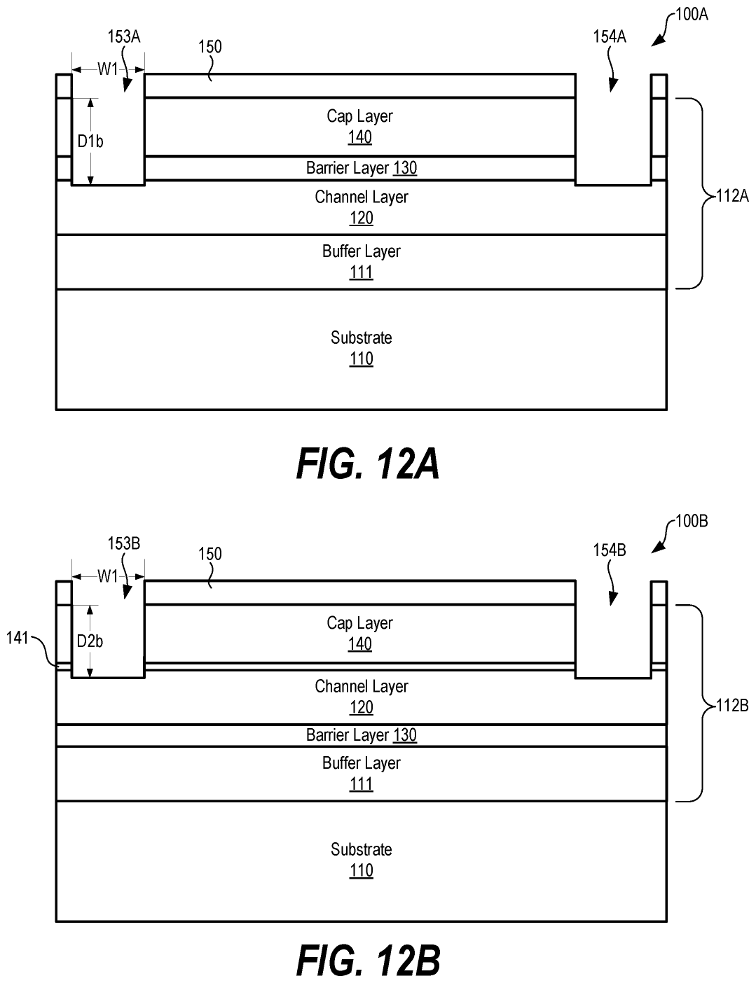

At step 308 in FIG. 9, the process includes etching away regions of the wafer provided at step 300. In one example, step 308 can be performed to increase the depth of the openings 153A and 154A shown in FIG. 11A or to increase the depth of the openings 153B and 154B shown in FIG. 11B, after step 306. In this case, step 308 can be performed to extend the openings 153A and 154A through the barrier layer 130, resulting in the deeper openings 153A and 154A shown in FIG. 12A. The openings 153A and 154A are extended to a depth “D1b” after the etching at step 308. Step 308 can also be performed to extend the openings 153B and 154B through the stop layer 141, as shown in FIG. 12B. The openings 153B and 154B are extended to a depth “D2b” after the etching at step 308. In either case, the openings can be extended down to the top surface of the channel layer 120 or down into the channel layer 120. Plasma etching, ME, DRIE, ICP, or other etching techniques can be relied upon at step 308. As compared to sublimed openings, the sidewalls of etched openings can have different shapes (e.g., different undercuts, ramp slopes, etc.), different crystal plane orientations, and other physical differences.

The illustration of the openings 153A and 154A are representative in FIGS. 11A and 12A. The final size of the opening 153A can be tailored or determined based on the width “W1” of the opening in the mask layer 150. The final size of the opening 154A can be tailored in a similar way. An aspect ratio of the opening 153A can be defined as a ratio of the depth “D1b” of the trench or opening 153A to the width “W1” of the trench or opening 153A (i.e., “D1b”/“W1”), and the aspect ratio of the opening 154A can be defined in a similar way. The aspect ratios of the openings 153A and 154A can vary, for example, depending on the type and desired electrical characteristics of the active device or devices being formed using the wafer 100A. The aspect ratios of the openings 153B and 154B can also vary depending on the type and desired electrical characteristics of the active device or devices being formed using the wafer 100B.

In some cases, step 306 can be skipped or omitted from the flow shown in FIG. 9. In this case, etching at step 308 can be performed to form the openings 153A and 154A shown in FIG. 12A, without sublimation at step 306. Etching at step 308 can also be performed to form the openings 153B and 154B shown in FIG. 12B, without sublimation at step 306.

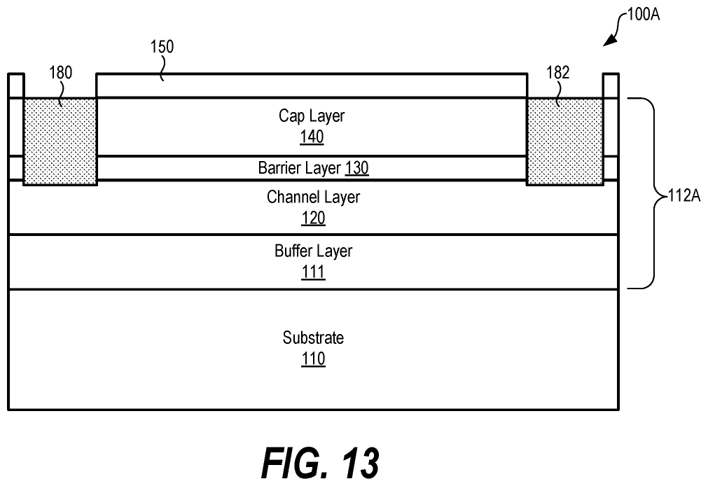

Referring again to FIG. 9, at step 310, the process includes depositing semiconductor materials, such as one or more layers of semiconductor materials, in the openings formed in steps 306 and 308. Referring to FIG. 13 as an example, the process can include growing regions 180 and 182 of semiconductor materials in the openings 153A and 154A of the wafer 100A (see FIG. 11A). The regions 180 and 182 of semiconductor materials can be grown or deposited in a chamber of an MBE tool at step 308, using MOCVD, or other techniques. As another example, step 308 can include growing similar regions of semiconductor materials in the openings 153B and 154B of the wafer 100B (see FIG. 12B).

The regions 180 and 182 can be embodied as highly-doped and conductive regions of GaN or GaN materials, to form ohmic contact areas or regions (e.g., source and drain regions) of a transistor. The semiconductor materials formed in the regions 180 and 182 can have a single crystal structure over the barrier layer 130 and between the exposed sidewalls of the cap layer 140 within the openings 153A and 154A. The semiconductor materials can also have a polycrystal structure in any areas where it is grown or deposited on the mask layer 150. The semiconductor materials having the polycrystal structure can be removed by liftoff of the mask layer 150, leaving the regions 180 and 182. Alternatively, due to the polycrystal structure, the semiconductor materials having the polycrystal structure can be selectively removed without removing the mask layer 150.

In other examples, step 310 can include depositing conductive materials in the openings formed in steps 306 and 308. In this case, the regions 180 and 182 in the wafers 100A and 100B can be embodied as conductive materials, including any of the metals and metal layers described above for the conductive materials 170. The conductive materials can be deposited by a physical deposition process, such as electron-beam deposition, sputtering, or another deposition process technique. In any case, the regions 180 and 182 can be embodied as conductive regions to form ohmic contact areas or regions (e.g., source and drain regions) of a transistor.

The process shown in FIG. 9 can be relied upon to prepare source and drain regions of a transistor in the wafers 100A and 100B. The process shown in FIG. 2 can be relied upon, separately, to form the gate of the transistor. The processes shown in FIGS. 2 and 9 can also be combined in various ways among the embodiments. The process shown in FIG. 9 can being performed first, followed by the process shown in FIG. 2. Alternatively, the process shown in FIG. 2 can being performed first, followed by the process shown in FIG. 9. In still other cases, the processes shown in FIGS. 2 and 9 can be combined in various ways. Masking layers (e.g., similar to the masking layer 150) can be formed over and removed from the wafers 100A and 110B, as needed, and openings can be formed through the masking layers to create the openings for the gate, source, and drain of the transistor through sublimation, etching, or both sublimation and etching.

As one example, a process for forming a transistor can start at step 300 in FIG. 9. After the etching at step 308 in FIG. 9, steps 202 and/or 204 in FIG. 2 can be performed, as needed, to form an opening through a mask layer for the gate of the transistor. Step 206 in FIG. 2 can then be performed to form the opening 152A in the wafer 100A (see FIG. 4A) or the opening 152B in the wafer 100B (see FIG. 4B). Either or both of steps 208 and 210 in FIG. 2 can be performed. At step 212 in FIG. 2, metal can be deposited to form the conductive materials 170 for the gate in either of the openings 152A or 152B, as well as to form conductive contacts over the regions 180 and 182 of semiconductor materials for source and drain contacts over the regions 180 and 182.

As another example, a process for forming a transistor can start at step 200 in FIG. 2. After sublimation is completed at step 206 in FIG. 2, a masking layer can be formed to fill the opening 152A in the wafer 100A (see FIG. 4A) or the opening 152B in the wafer 100B (see FIG. 4B). Then, steps 304, 306, and 308 (or just steps 304 and 308) in FIG. 9 can be performed to form the openings 153A and 154A at the sides of the opening 152A in the wafer 100A or to form the openings 153B and 154B at the sides of the opening 152B in the wafer 100B. Masking layers can then be removed, and new masking layers can be formed and patterned, as needed, to expose the openings 152A, 153A, and 154A in the wafer 100A or the openings 152B, 153B, and 154B in the wafer 100B. Conductive materials, including one or more layers of metal, silicide, highly-doped and conductive regions of semiconductor materials, or other conductive materials can then be grown or deposited in the openings 152A, 153A, and 154A in the wafer 100A or in the openings 152B, 153B, and 154B in the wafer 100B as part of steps 212 and step 310 in FIGS. 2 and 9, in any suitable combination.

As another example, the openings 152, 153, and 154 can be formed through the mask layer 150 over either of the wafers 100A or 100B at the same time. Sublimation can be performed, as at step 206 in FIG. 2 (or as at step 306 in FIG. 9), until the cap layer 140 is removed within each of the openings 152, 153, and 154. The cap layer 140 can be removed using sublimation down to the barrier layer 130 for the wafer 100A or removed down to the stop layer 141 for the wafer 100B. In this case, the openings 152A, 153A, and 154A in the wafer 100A (see FIGS. 4A and 11A) or the openings 152B, 153B, 154B in the wafer 100B (see FIGS. 4B and 11B) can be formed together and at the same time using sublimation rather than etching. Thus, the openings for the source, drain, and gate can be formed at the same time and using the same process step for high levels of alignment. The openings 153A and 154A in the wafer 100A or the openings 153B and 154B in the wafer 100B can then be extended to a further depth according to step 308 in FIG. 9. The extension of the openings 153A, 154A, 153B, and 154B by etching can track or follow the sidewalls of the openings previously formed through sublimation, to maintain the alignment.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

The transistors described herein can be formed as field effect transistors (FETs), although the concepts can be applied to other types of transistors. Among other types of FET transistors, the transistors described herein can be formed as HEMTs, pseudomorphic high-electron mobility transistors (pHEMTs), metamorphic high-electron mobility transistors (mHEMTs), among other types of transistors. The FETs can include metal oxide or insulator semiconductors (MOSFET or MISFET) transistors and metal-semiconductor field-effect transistor (MESFETs). The transistors can include one or more field plates, such as source-connected field plates, gate-connected field plates, or both source-connected and gate-connected field plates. Overall, the processing techniques described herein aid in the formation of active devices having relatively thinner barrier layers and relatively thicker cap layers. Beyond transistors, other GaN-based or III-Nitride-based active devices can also incorporate the processing techniques described herein to form active devices having smaller features with high precision. The smaller features, such as thinner barrier layers and smaller gate lengths, result in active devices capable of higher frequency operation and other characteristics preferrable for certain applications.

The concepts described herein may be embodied as methods, in the form of semiconductor structures, in the form of semiconductor devices, and in other ways. The steps or actions performed in such methods may be ordered in any suitable way, and the embodiments may be performed in an order that is different than that described in the examples above. Certain steps or actions can also be performed at the same time or overlapping in time (e.g., concurrently or with partial concurrence) in some cases, although described as occurring sequentially. Additionally, the methods can include additional steps or actions in addition to those described, and the methods can omit one or more of the steps or actions described.

The precision of the layers (e.g., the precision of the thicknesses, doping concentrations, etc.) and other features described herein (e.g., the exact sizes of the openings) are limited, to some extent, by the capabilities of the particular manufacturing techniques, processing techniques, and manufacturing steps and tools used to form the layers and features. For example, certain epitaxial growth techniques offer finer or more exacting layer thicknesses than other techniques, certain deposition techniques offer finer or more exacting layer thicknesses than other techniques, and certain etching techniques offer finer or more exacting subtractive techniques, and all of these techniques can vary in precision based on the type(s) of materials being processed. In any case, the use of sublimation, as described herein, provides a more precise subtractive technique than etching techniques. In one example, the use of sublimation to remove one or more layers of gallium nitride materials excluding or without aluminum and to stop on one or more layers of semiconductor materials including aluminum provides a more precise subtractive technique than etching.

In view of the limitations of the semiconductor manufacturing and processing techniques available in the field, the terms “approximately” and “about” reflect a certain inability (or uncertainty) to precisely control the exact dimensions of the layers and features described herein. The terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A method of fabricating a semiconductor structure using sublimation, comprising:
forming an opening through a mask layer over a wafer, the wafer comprising a substrate, a channel layer over the substrate, a barrier layer over the channel layer, and a cap layer over the barrier layer;
subliming away a region of the cap layer, within the opening in the mask layer, to form an opening in the cap layer down to a top surface of the barrier layer; and
depositing a conductive material into the opening in the cap layer.

2. The method of claim 1, wherein the barrier layer comprises aluminum nitride and the cap layer comprises gallium nitride.

3. The method of claim 1, wherein the barrier layer comprises aluminum nitride and the cap layer comprises an aluminum gallium nitride alloy.

4. The method of claim 1, wherein the barrier layer comprises a first material, the cap layer comprises a second material, and the second material sublimes away at a lower temperature than the first material.

5. The method of claim 1, wherein the subliming is performed in a vacuum environment inside a processing chamber within a temperature range.

6. The method of claim 5, wherein the subliming is performed in a vacuum environment at a pressure of greater than or equal to 10⁻⁸ Torr and a temperature of greater than or equal to 750° C. and less than or equal to 1300° C. inside the processing chamber.

7. The method of claim 4, further comprising, before depositing the conductive material, forming an insulating layer over a top surface of the barrier layer within the opening in the cap layer.

8. The method of claim 4, further comprising, before depositing the conductive material, forming a recap layer of semiconductor materials over a top surface of the barrier layer within the opening in the cap layer.

9. The method of claim 1, wherein:
forming the opening comprises forming at least two openings through the mask layer; and
subliming away the region comprises subliming away a respective region of the cap layer within each of the at least two openings in the mask layer, to form at least two openings in the cap layer down to a top surface of the barrier layer.

10. The method of claim 9, wherein depositing the conductive material comprises depositing the conductive material into the at least two openings in the cap layer.

11. A semiconductor structure, comprising:
a substrate;
a channel layer over the substrate;
a barrier layer over the channel layer;
a cap layer over the channel layer, the cap layer comprising a sublimed opening, the sublimed opening extending from a top surface of the channel layer to a top surface of the barrier layer; and
a conductive material in the sublimed opening.

12. The semiconductor structure of claim 11, wherein the barrier layer comprises aluminum nitride and the cap layer comprises an aluminum gallium nitride alloy.

13. The semiconductor structure of claim 11, further comprising an insulating layer between the top surface of the barrier layer and the conductive material in the sublimed opening.

14. The semiconductor structure of claim 11, wherein the barrier layer has a thickness between 0.3-5 nm.

15. The semiconductor structure of claim 11, wherein the cap layer further comprises an etched opening and conductive material in the etched opening.

16. A method of fabricating a transistor using sublimation, comprising:
forming openings through a mask layer over a wafer, the wafer comprising a channel layer, a barrier layer, and a cap layer over a substrate;
subliming away a first region of the cap layer, within a first opening in the mask layer, to form a first opening through the cap layer;
etching away a second region of the cap layer, within a second opening in the mask layer, to form a second opening through the cap layer; and
depositing a conductive material into the first opening for a gate of the transistor and into the second opening for a drain or a source of the transistor.

17. The method of claim 16, wherein:
the wafer comprises the channel layer over the substrate, the barrier layer over the channel layer, and the cap layer over the barrier layer;
the barrier layer comprises aluminum nitride and the cap layer comprises an aluminum gallium nitride alloy; and
the first opening is formed through the cap layer and down to the barrier layer.

18. The method of claim 16, wherein:
the wafer comprises the barrier layer over the substrate, the channel layer over the barrier layer, a stop layer over the channel layer, and the cap layer over the stop layer;
the stop layer comprises aluminum nitride and the cap layer comprises an aluminum gallium nitride alloy; and
the first opening is formed through the cap layer and down to the stop layer.

19. The method of claim 16, further comprising, before depositing the conductive material, forming an insulating layer within the first opening in the cap layer.

20. The method of claim 16, further comprising, before depositing the conductive material, depositing semiconductor materials within the first opening in the cap layer.
